(19) United States
(12) Patent Application Publication
(10) Pub. No.: US 2013/0299840 A1
(43) Pub. Date: Nov. 14, 2013

(54) SCHOTTKY BARRIER DIODE AND MANUFACTURING METHOD THEREOF

(71) Applicants: Chieh-Hsiung Kuan, Taipei City (TW); Ting-Wei Liao, Taichung City (TW); Chien-Wei Chiu, Yunlin County (TW); Tsung-Yi Huang, Hsinchu City (TW)

(72) Inventors: Chieh-Hsiung Kuan, Taipei City (TW); Ting-Wei Liao, Taichung City (TW); Chien-Wei Chiu, Yunlin County (TW); Tsung-Yi Huang, Hsinchu City (TW)

(73) Assignee: Richtek Technology Corporation

(21) Appl. No.: 13/466,550

(22) Filed: May 8, 2012

(51) Int. Cl. H01L 29/20; H01L 21/28; H01L 29/872

(52) U.S. Cl. 257/76; 257/471; 438/571; 257/E29.089; 257/E29.338; 257/E21.158

(57) ABSTRACT

The present invention discloses a Schottky barrier diode (SBD) and a manufacturing method thereof. The SBD includes: a semiconductor layer, which has multiple openings forming an opening array; and an anode, which has multiple conductive protrusions protruding into the multiple openings and forming a conductive array; wherein a Schottky contact is formed between the semiconductor layer and the anode.

### BACKGROUND OF THE INVENTION

1. Field of Invention

The present invention relates to a Schottky barrier diode (SBD) and a manufacturing method of an SBD; particularly, it relates to such SBD having a semiconductor layer which includes an opening array, and a manufacturing method thereof.

2. Description of Related Art

A Schottky barrier diode (SBD) is a semiconductor device. Compared to a P-N junction diode, the SBD has a higher forward current and a shorter recovery time in operation because of a Schottky barrier formed by Schottky contact between a metal layer and a semiconductor layer. However, the SBD has a higher leakage current and therefore more power loss in a reverse biased operation because of an anode made of conductive materials.

To overcome the drawback in the prior art, the present invention proposes an SBD and a manufacturing method thereof, wherein a work function of the conductive material is adjusted by forming an opening array in the semiconductor layer, to decrease the leakage current in the reverse biased operation such that the power loss is decreased.

### SUMMARY OF THE INVENTION

A first objective of the present invention is to provide a Schottky barrier diode (SBD).

A second objective of the present invention is to provide a manufacturing method of an SBD.

To achieve the objectives mentioned above, from one perspective, the present invention provides an SBD, including: a semiconductor layer, which has a plurality of openings forming an opening array; and an anode, which has a plurality of conductive protrusions protruding into the plural openings and forming a conductive array; wherein a Schottky contact is formed between the semiconductor layer and the anode.

From another perspective, the present invention provides a manufacturing method of an SBD, including: providing a semiconductor layer; forming a plurality of openings downward from an upper surface of the semiconductor layer to form an opening array; and forming a plurality of conductive protrusions in the openings to form a conductive array, and thereby forming an anode; wherein a Schottky contact is formed between the semiconductor layer and the anode.

In one embodiment, the semiconductor layer preferably includes a gallium nitride (GaN) layer or a silicon (Si) layer.

In another preferable embodiment, each of the openings is a nanohole structure formed from an upper surface of the semiconductor layer downward, by a lithography process and an etch process.

In another embodiment, the SBD preferably further includes a conductive layer formed on the semiconductor layer, wherein an ohmic contact is formed between the semiconductor layer and the conductive layer.

In another preferable embodiment, the openings have an average diameter not larger than 300 nm, a pitch between the openings not larger than 1 um, and a depth between 50 nm to 200 nm from an upper surface of the semiconductor layer downward.

The objectives, technical details, features, and effects of the present invention will be better understood with regard to the detailed description of the embodiments below.

### BRIEF DESCRIPTION OF THE DRAWINGS

FIGS. 1A-1E show a first embodiment of the present invention.

FIG. 2 shows a second embodiment of the present invention.

FIG. 3 shows a third embodiment of the present invention.

FIGS. 4A-4B show dimensions of the openings and the conductive protrusions schematically.

FIGS. 5 and 6 show two examples illustrating that the shape of the openings is not limited to a circle.

FIG. 7 shows a fourth embodiment of the present invention.

### DESCRIPTION OF THE PREFERRED EMBODIMENTS

The drawings as referred to throughout the description of the present invention are for illustration only, to show the interrelations between the regions and the process steps, but not drawn according to actual scale.

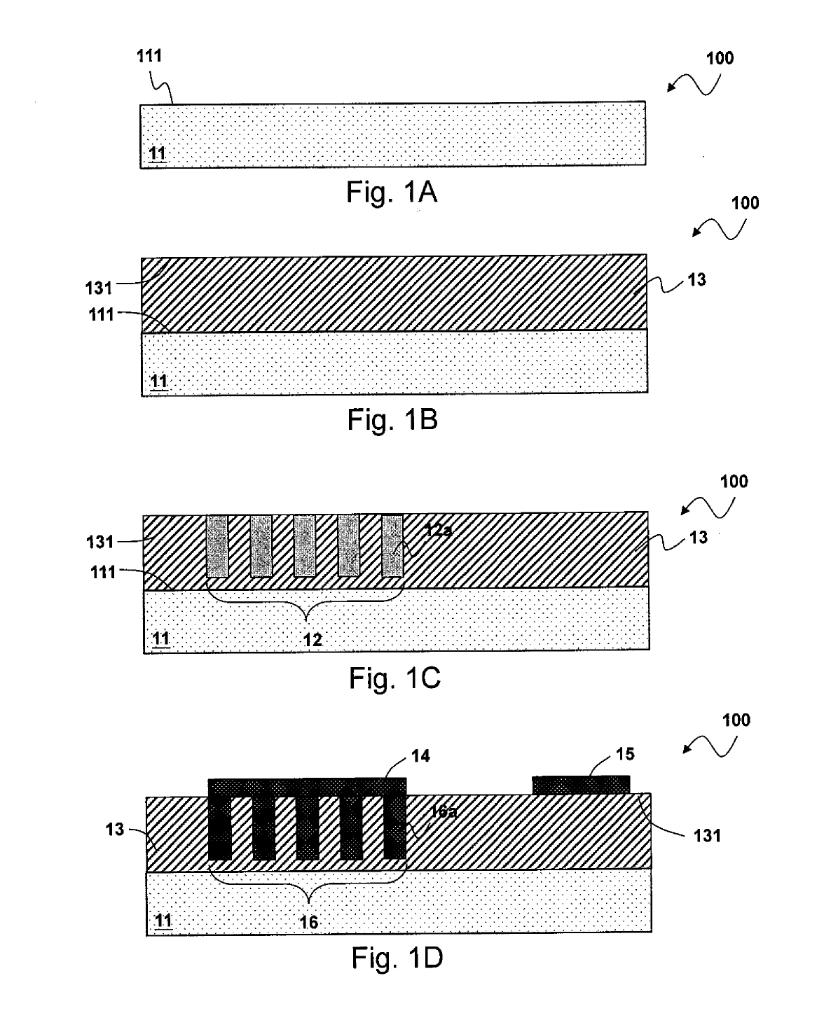

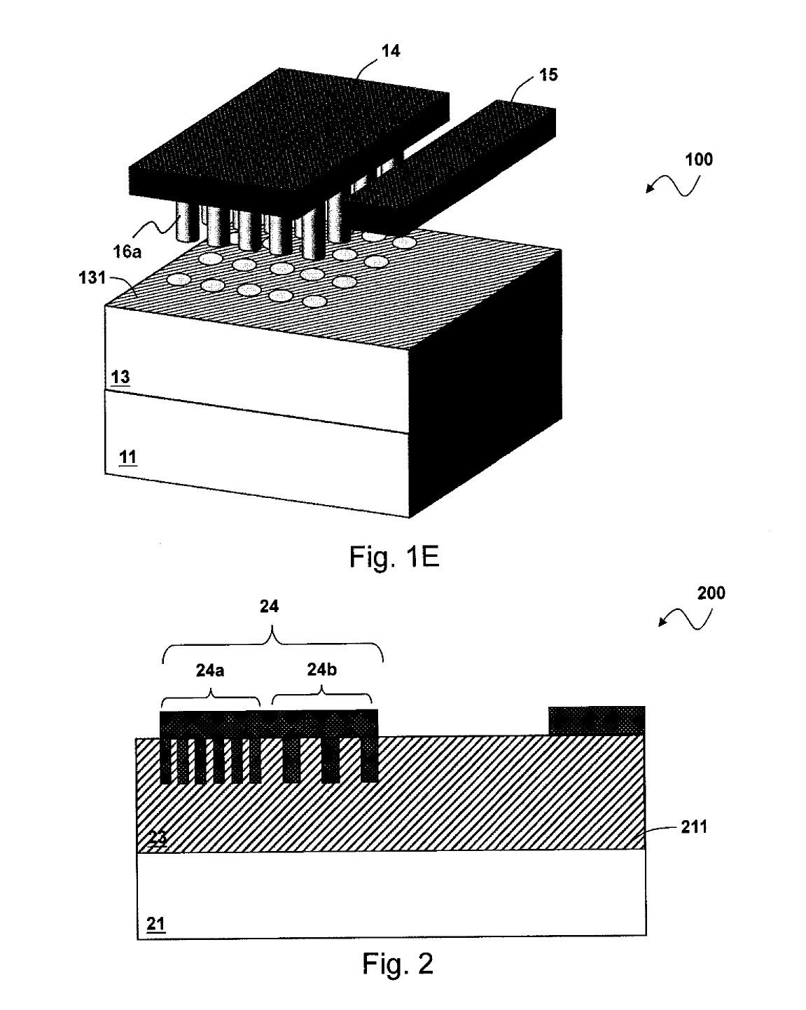

FIGS. 1A-1E show a first embodiment of the present invention. FIGS. 1A-1D are schematic cross-section diagrams showing a manufacturing flow of a Schottky barrier diode (SBD) 100 according to this embodiment. As shown in FIG. 1A, first, a substrate 11 is provided, which has an upper surface 111. The substrate 11 is for example but not limited to a silicon carbide (SiC) substrate or a sapphire substrate.

Next, referring to FIG. 1B, a semiconductor layer 13 is formed on the upper surface 111. The semiconductor layer 13 has an upper surface 131 which does not face the upper surface 111, as shown in the figure. The semiconductor layer 13 is for example but not limited to a gallium nitride (GaN) layer or a silicon (Si) layer.

Next, as shown in FIG. 1C, multiple openings 12a are formed in the semiconductor layer 13 from the upper surface 113 downward, by for example but not limited to a lithograph process and an etching process. The multiple openings 12a form an opening array 12 from top view (not shown). The aforementioned etching process for example can be, but not limited to, an inductively coupled plasma reactive ion etching (ICP-RIE) process. The opening 12a is for example but not limited to a nanohole structure.

Next, referring to FIG. 1D, in the semiconductor layer 13, multiple conductive protrusions 16a are formed in the multiple openings 12a, and thus a conductive array 16 is formed. As shown in the figure, an anode 14 is formed by the conductive array 16. A cathode 15 is formed on an upper surface 131 away from the anode 14. A Schottky contact is formed between the anode 14 including the conductive array 16, and the semiconductor layer 13. An ohmic contact is formed between the cathode 15 and the semiconductor layer 13. Therefore, the anode 14 (including the conductive array 16), the semiconductor layer 13, and the cathode 15 form the SBD 100.

FIG. 1E shows a schematic 3D view of this embodiment. It should be noted that, in order to better illustrate the major feature of the present invention, the anode 14 including the conductive protrusions 16a and the cathode 15 are shown separated from the semiconductor layer 13 in FIG. 1E, but they should be in contact with the semiconductor layer 13 in a practical device. According to the present invention, the topography variation of the contact surface between the anode 14 (conductive array 16) and the semiconductor layer 13 helps to adjust the work function of the conductive material of the anode 14, such that the characteristic of the SBD can be adjusted, such as to achieve a higher forward current, a higher breakdown voltage in reverse operation, or lower power loss, etc.

FIG. 2 shows a second embodiment of the present invention. FIG. 2 is a schematic cross-section diagram showing an SBD 200 according to this embodiment. As shown in FIG. 2, similar to the first embodiment, first, a substrate 21 is provided. The substrate 21 is for example but not limited to the SiC substrate or a sapphire substrate. Next, a semiconductor layer 23 is formed on an upper surface 211. The semiconductor layer 23 is for example but not limited to the GaN layer or the Si layer. This embodiment is different from the first embodiment in that, the anode 24 includes a first region 24a and a second region 24b. As shown in the figure, conductive protrusions of the first region 24a have a shorter diameter compared to the diameter of the conductive protrusions of the second region 24b, and a pitch of the conductive protrusions of the first region 24a is also shorter. The advantage of this arrangement is that, for example, the conductive protrusions formed in two regions 24a and 24b of the anode 24 may have two different work functions, such that the SBD 200 may have a higher forward current in a forward biased operation, and a lower leakage current in a reverse biased operation with a higher breakdown voltage.

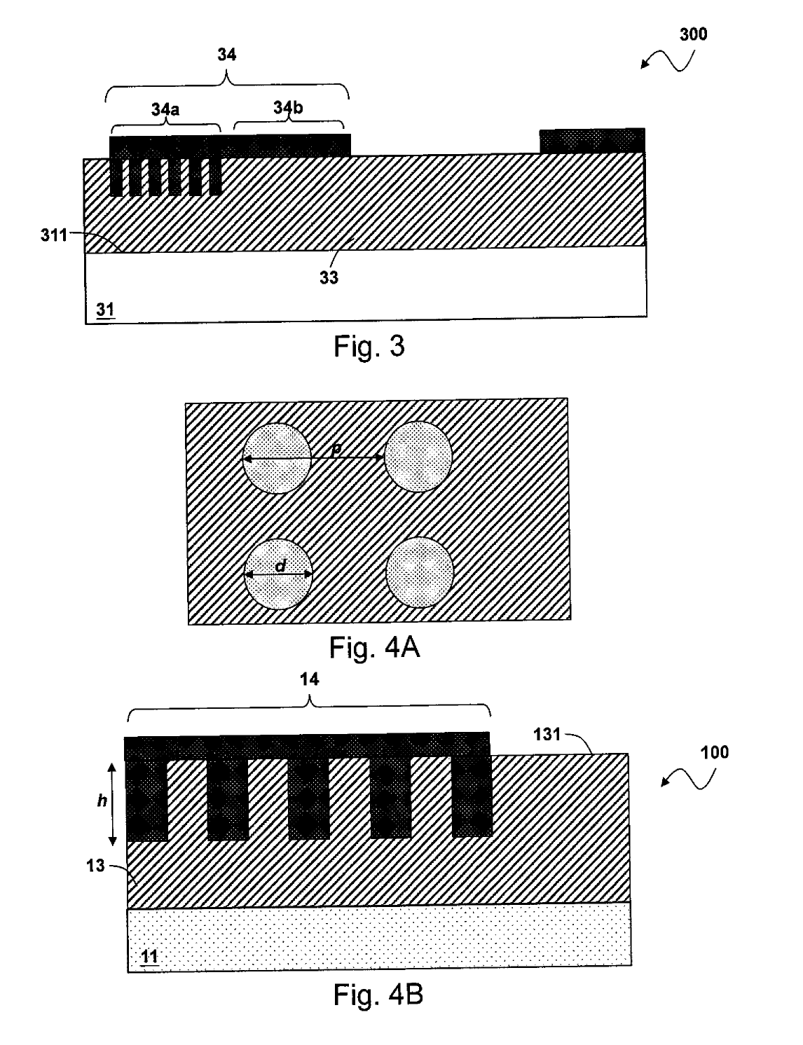

FIG. 3 shows a third embodiment of the present invention. FIG. 3 is a schematic cross-section diagram showing an SBD 300 according to this embodiment. As shown in FIG. 3, similar to the second embodiment, first, a substrate 31 is provided. The substrate 31 is for example but not limited to the SiC substrate or a sapphire substrate. Next, a semiconductor layer 33 is formed on an upper surface 311. The semiconductor layer 33 is for example but not limited to the GaN layer or the Si layer. This embodiment is different from the second embodiment in that, the anode 34 includes a first region 34a and a second region 34b. As shown in the figure, the first region 34a has conductive protrusions, but the second region 34b has not. This embodiment illustrates that, according to the present invention, the anode of the SBD may have different work functions at different regions by having or not having the conductive protrusions.

FIGS. 4A-4B show preferable dimensions of the openings and the conductive protrusions. As shown in FIG. 4A, the openings have an average diameter d preferably not larger than 300 nm, and a pitch p between the openings not larger than 1 um. As shown in FIG. 4B, wherein the first embodiment is taken as an example, a depth h downward from the upper surface 131 of the semiconductor layer 13 is preferably between 50 nm to 200 nm.

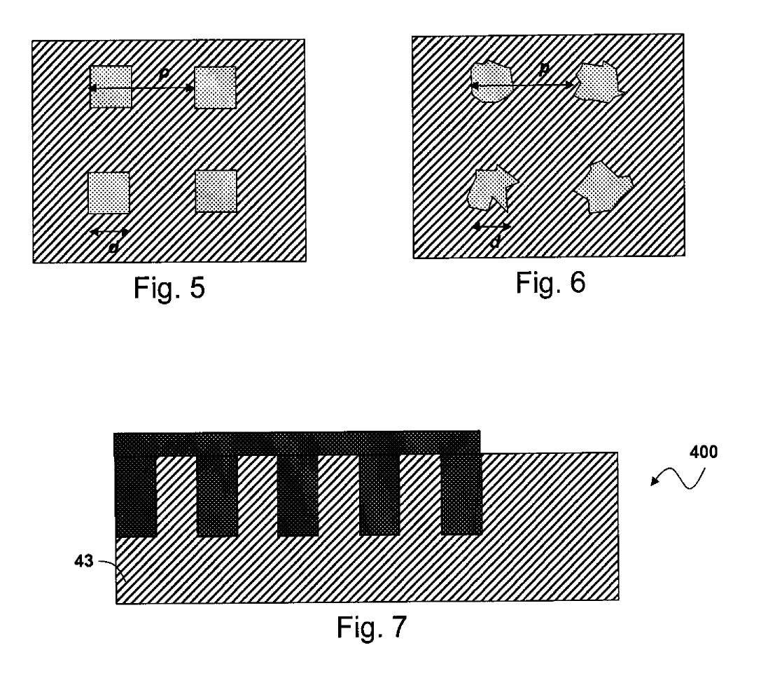

FIGS. 5 and 6 show two examples of the shape of the openings, to illustrate that the shape is not limited to a circle as shown in all the aforementioned embodiments, but it may be a rectangular or any other regular or irregular shape. The dimensions of these rectangular or irregular openings can be designed with reference to the aforementioned preferable dimensions.

FIG. 7 shows a fourth embodiment of the present invention. FIG. 7 is a schematic cross-section diagram showing an SBD 400 according to this embodiment. This embodiment is different from the first embodiment in that, the semiconductor layer 43 of this embodiment is not formed on any substrate. That is, the substrates 11, 21 and 31 are not necessarily required in the present invention. For example, if the semiconductor layer is a Si semiconductor layer, it does not need to be formed on a substrate.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristics of the device, such as an aluminum gallium nitride (AlGaN) layer between the semiconductor layer and the anode in the SBD, can be added. For another example, the semiconductor layer may be P-type or N-type in the SBD. In view of the foregoing, the spirit of the present invention should cover all such and other modifications and variations, which should be interpreted to fall within the scope of the following claims and their equivalents.

1. A Schottky barrier diode (SBD), comprising:
a semiconductor layer, which has a plurality of openings forming an opening array; and
an anode, which has a plurality of conductive protrusions protruding into the openings and forming a conductive array;
wherein a Schottky contact is formed between the semiconductor layer and the anode.

2. The SBD of claim 1, wherein the semiconductor layer includes a gallium nitride (GaN) layer or a silicon (Si) layer.

3. The SBD of claim 1, wherein each of the openings is a nanohole structure formed from an upper surface of the semiconductor layer downward, by a lithography process and an etch process.

4. The SBD of claim 1, further comprising a conductive layer formed on the semiconductor layer, wherein an ohmic contact is formed between the semiconductor layer and the conductive layer.

5. The SBD of claim 1, wherein the openings have an average diameter not larger than 300 nm, a pitch between the openings not larger than 1 um, and a depth between 50 nm to 200 nm from an upper surface of the semiconductor layer downward.

6. A manufacturing method of a Schottky barrier diode (SBD), comprising:
providing a semiconductor layer;
forming a plurality of openings downward from an upper surface of the semiconductor layer to form an opening array; and
forming a plurality of conductive protrusions in the plural openings to form a conductive array, and thereby forming an anode;
wherein a Schottky contact is formed between the semiconductor layer and the anode.

7. The manufacturing method of claim 6, wherein the semiconductor layer includes a gallium nitride (GaN) layer or a silicon (Si) layer.

8. The manufacturing method of claim 6, wherein the step of forming the opening includes forming a nanohole structure from an upper surface of the semiconductor layer downward by a lithography process and an etch process.

9. The manufacturing method of claim 6, further comprising forming a conductive layer on the semiconductor layer, wherein an ohmic contact is formed between the semiconductor layer and the conductive layer.

10. The manufacturing method of claim 6, wherein the opening has an average diameter not larger than 300 nm, a pitch between the openings not larger than 1 um, and a depth between 50 nm to 200 nm from an upper surface downward.
